(19) United States
(12) Patent Application Publication
(10) Pub. No.: US 2009/0001489 A1
(43) Pub. Date: Jan. 1, 2009

(54) SILICON PHOTODETECTOR AND METHOD FOR FORMING THE SAME

(76) Inventors: Yue-Ming Hsin, Tainan City (TW); Wei-Kuo Huang, Taipei City (TW); Yu-Chang Liu, Waipu Township (TW)

Correspondence Address: Charles G. Mersereau;NIKOLAI & MERSEREAU, P.A., S., # 820, 900 Second Ave., Minneapolis, MN, 55402, US

(21) Appl. No.: 11/768,721

(22) Filed: Jun. 26, 2007

(51) Int. Cl. H01L 31/00

(52) U.S. Cl. 257/431; 438/57; 257/E31.001

(57) ABSTRACT

A structure of a silicon photodetector and a method for forming the same by using the conventional CMOS semiconductor manufacturing process and micro-electromechanical system manufacturing process, in which the micro-electromechanical system manufacturing process (lateral etching process) is applied for elimination of effect and interference caused by a substrate of the silicon photodetector after optical absorption thereof, thereby greatly improving the response speed of the silicon photodetector. This can be done only by applying the lateral etching process onto a portion of the substrate of the silicon photodetector after the semiconductor manufacturing process is finished, through which slow diffusion carriers produced from the optical absorption of the substrate can be effectively reduced and the response speed is thus enhanced.

### BACKGROUND OF THE INVENTION

1. Field of Invention

The present invention relates to a structure of a silicon photodetector and a method for forming the structure by using the conventional CMOS semiconductor manufacturing process and micro-electromechanical system manufacturing process to eliminate effect and interference caused by a substrate of the silicon photodetector after optical absorption thereof and thus enhances the response speed of the silicon photodetector.

2. Description of the Related Art

There have been many technologies for manufacturing a silicon optoelectronic integrated circuit in a single chip with silicon photodetector and a receiver circuit combined therein. In most of photodetectors, an electric field is used to speed up carriers produced by an optical excitation and move them rapidly towards the direction of the electric field. However, the electric field has a limited range and thus the carriers beyond the range are otherwise forced to an electrode by means of diffusion. Since light having the wavelength of 850 nm has a great transmittance through the silicon material, the problem of slowly diffused carriers resulted from that the substrate absorbs the light has to be addressed, so that a high speed application can thus be achieved. An effective solution to this problem is that blocking the slow diffused carriers from the substrate by a silicon-on-insulating technology. However, such a process for the substrate is very costly.

### SUMMARY OF THE INVENTION

It is an object of the present invention to provide a structure of a silicon photodetector and a method for forming the structure by using the conventional CMOS semiconductor manufacturing process and micro-electromechanical system manufacturing process.

The photodetector is one of the important optical communications elements and used for converting an optical signal into an electrical signal. The conventional photodetector is manufactured with the III-V compound semiconductor which is relatively costly. In this present invention, the photodetector is otherwise fabricated with the conventional CMOS and micro-electromechanical system manufacturing process, which is formed with a relatively inexpensive material and a better integrity.

As compared to the prior art, the inventive photodetector is aimed to eliminate effect and interference caused by a substrate of the silicon photodetector after optical absorption thereof, by using the conventional CMOS and micro-electromechanical system manufacturing process (lateral etching process), and thus enhances the responsive speed of the silicon photodetector.

In addition, in an array formed of such photodetectors it is effective to soothe the problem of interference brought about by the neighboring photodetectors for any one of the photodetectors in the same array.

### BRIEF DESCRIPTION OF THE DRAWINGS

The above and other objects of the present invention will become readily apparent by reference to the following detailed description when considered in conjunction with the accompanying drawings wherein:

FIG. 1 is a schematic cross-sectional diagram illustrating a conventional method for improving a photodetector by using the silicon-on-insulating layer technology;

FIG. 2 is a cross sectional diagram of a structure of a conventional photodetector;

FIG. 3 is a schematic diagram of a structure of the photodetector according to the present invention;

FIG. 4 is a diagram of a simulated structure of the conventional photodetector;

FIG. 5 is a diagram of a simulated structure of the photodetector according to the present invention, in which the silicon-on-insulating layer technology has been applied;

FIG. 6 is a diagram of a simulated structure of the photodetector, in which a lateral etching up to 2 μm has been applied, according to the present invention;

FIG. 7 is a diagram of a simulated structure of the photodetector, in which a lateral etching up to 4 μm has been applied, according to the present invention;

FIG. 8 is a diagram of a simulated structure of the photodetector, in which a lateral etching up to 6 μm has been applied, according to the present invention;

FIG. 9 is a diagram of a simulated structure of the photodetector, in which a lateral etching up to 8 μm has been applied, according to the present invention;

FIG. 10 is a simulated optical intensity versus frequency plot obtained in the conventional photodetector;

FIG. 11 is a simulated optical intensity versus frequency plot obtained by using the silicon-on-insulating layer technology;

FIG. 12 is a diagram of a simulated structure of the photodetector, in which a lateral etching up to 2 m has been applied, according to the present invention;

FIG. 13 is a simulated optical intensity versus frequency plot of the structure of the photodetector, in which a lateral etching up to 4 μm has been applied, according to the present invention;

FIG. 14 is a simulated optical intensity versus frequency plot of the structure of the photodetector, in which a lateral etching up to 6 μm has been applied, according to the present invention;

FIG. 15 is a simulated optical intensity versus frequency plot of the structure of the photodetector, in which a lateral etching up to 8 μm has been applied, according to the present invention;

FIG. 16 is a relationship plot of bandwidth and response as a function of the etching depth which varies of the structure according to the present invention; and

FIG. 17 is feature table of the conventional structure, silicon-on-insulating layer structure and the structure according to the present of the present invention.

### DETAILED DESCRIPTION OF THE INVENTION

The present invention is a silicon photodetector and a method for forming the same, which will be described taken in the preferred embodiments with reference to the accompanying drawings.

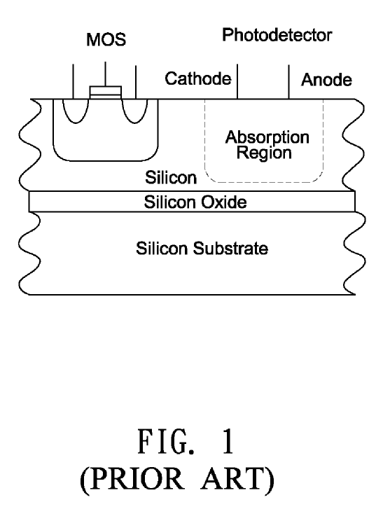

Referring to FIG. 1, in the conventional complement metal oxide semiconductor (CMOS) manufacturing process, it is possible to form a photodetector and CMOS transistor concurrently. The photodetector may be used for absorbing an incoming optical signal and converting the optic signal into an electric signal. At a region where is reachable by an electric field, carriers therein can be speed up by excitation of light.

MOS field-effect transistor (FET) is an electronic component which is generally served as a basis for forming various kinds of circuits. In FIG. 1, a schematic diagram showing the technology of silicon-on-insulating layer to improve the resulting photodetector used in the prior art is depicted. In the structure, the insulating layer exists between the thus formed photodetector and a silicon substrate. An advantage of this structure is that the slow diffusing carriers produced from the substrate after absorbing light impinged thereon can be blocked. However, such structure is relatively costly.

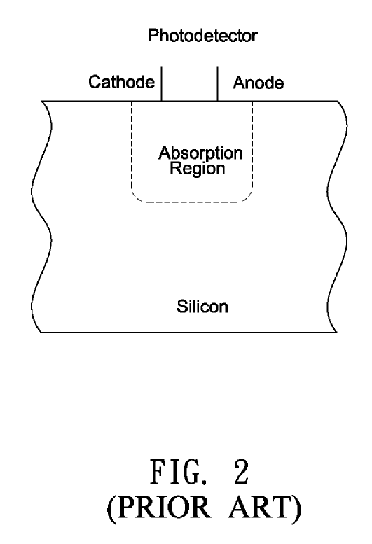

Referring to FIG. 2, in the photodetector fabricated by the conventional CMOS manufacturing process, an electric field is used to speed up carriers produced from excitation of where the electric field reaches. However, the electric field can only reach a limited range and carriers excited by light are forced to an electrode by diffusion. In this regard, the issue of the slow diffusing carriers resulting from absorption of the light of the substrate has to be overcome and then a high speed application can become possible.

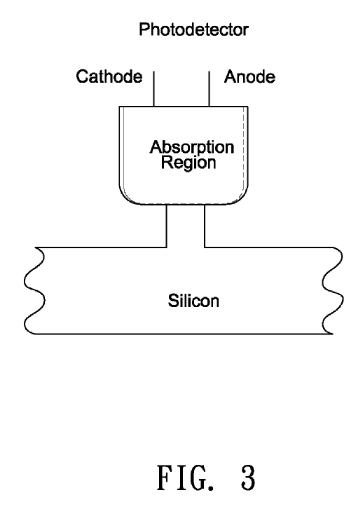

Referring to FIG. 3, any kind of photodetectors formed by using the conventional CMOS manufacturing process is subject to a micro-electromechanical manufacturing process (lateral etching process) or any process which can effectively eliminate the substrate underlying the photodetector device. Through this manufacturing process, a large portion of the optical excited carriers can be eliminated and thus the response speed of the thus formed photodetector can be enhanced.

In this invention, the formed photodetector is simulated for some performances to demonstrate the recited advantages thereof by using the software MEDICI commercially available from Synopsys.

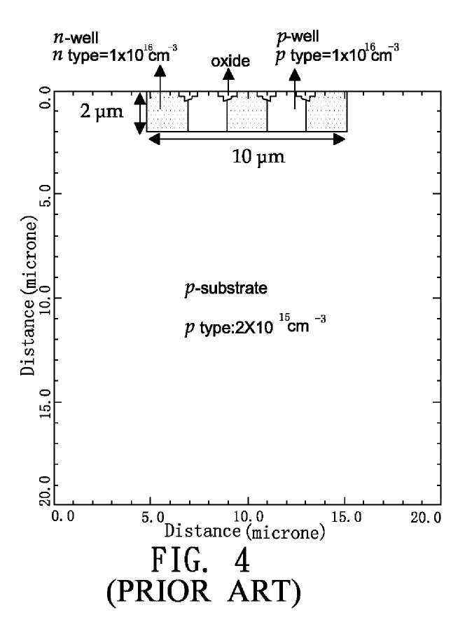

Referring to FIG. 4, a simulated structure diagram of the prior photodetector is shown therein. This structure is formed by silicon with a p-type substrate, a concentration of 2×10¹⁵ number/cm⁻³ and a thickness of 20 μm. Between a p-type well and an n-type well, a silicon dioxide material is disposed to separate them. The simulated photodetector is designed with a p- and n-type well alternating structure having a width of 10 μm, to see the responsive characteristics of the photodetctor.

In the simulation process, light of different frequencies and having a modulation wavelength of 850 nm is inputted to the photodetector, the light having an altitude of 10 μm, a width of 10 μm and an illuminating amount of 1×10²¹ (photons/cm²-sec). As the frequency responses obtained from the photodetector after being impinged with the modulated light with different frequencies are known, a negative 3 dB bandwidth of the photodetector can be thus obtained. In the simulation process, different negative bias voltages are also applied. As the applied negative bias voltage becomes larger, the electric field applied is larger which causes a depletion region of the photodetector to be also larger. At this time, the bandwidth becomes larger due to the electric field speeding up the carriers and the optical response also becomes more significant as the depletion region increases.

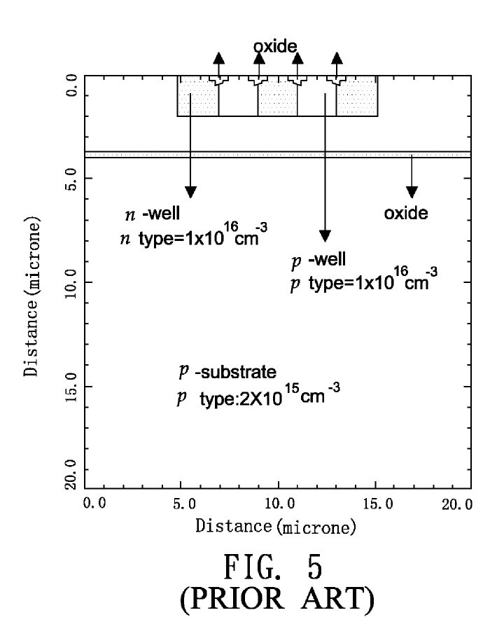

Referring to FIG. 5, a simulated structure with an insulating layer inserting in silicon is schematically shown therein. This structure is identical to that schematically shown in FIG. 4, including the adopted concentration and range thereof, except that a silicon dioxide layer is provided between the substrate and the photodetector. The silicon dioxide is provided for blocking slow carriers resulted from exposure of the substrate to light.

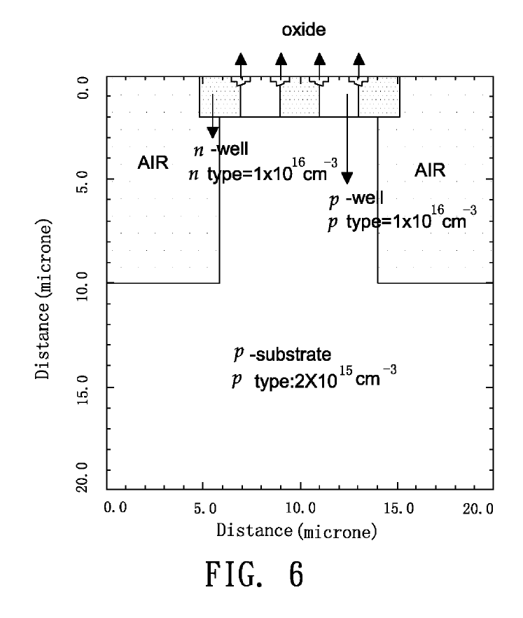

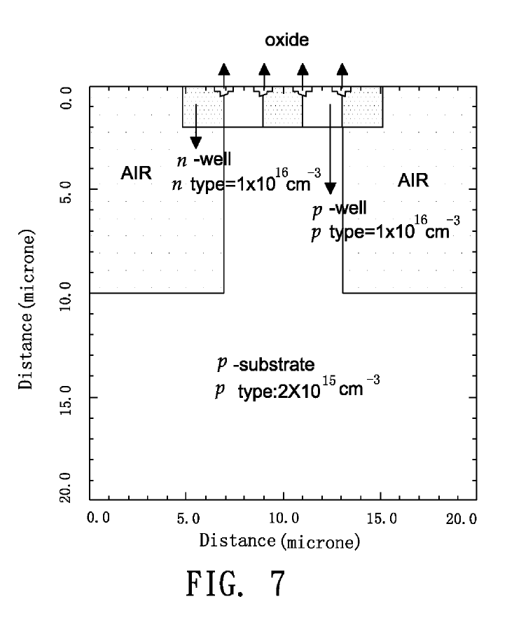

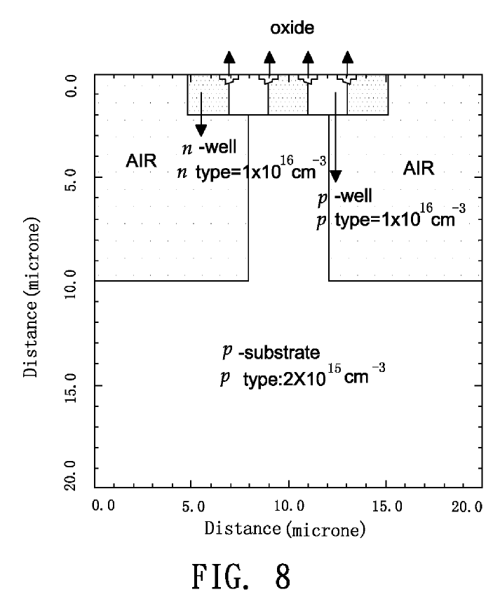

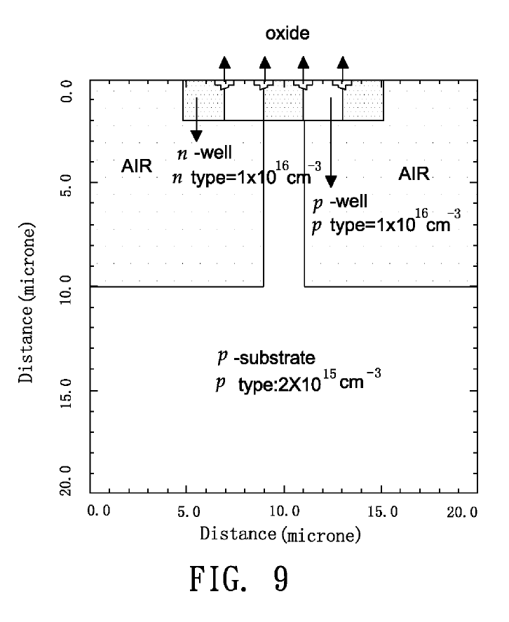

Referring to FIG. 6 through FIG. 9, simulated structures of the inventive photodetector having been subject to the lateral etching process are schematically shown therein. Likewise, the adopted concentration and range of this structure are identical to those provided for the structure shown in FIG. 4. The only difference is that the present structure is assumed to have undergone some lateral etching processes of different depths: 2 μm (FIG. 6), 4 μm (FIG. 7), 6 μm (FIG. 8) and 8 μm (FIG. 9), compared with a width of the photodetector 10 μm. These structures are respectively simulated and examined for their optical responses

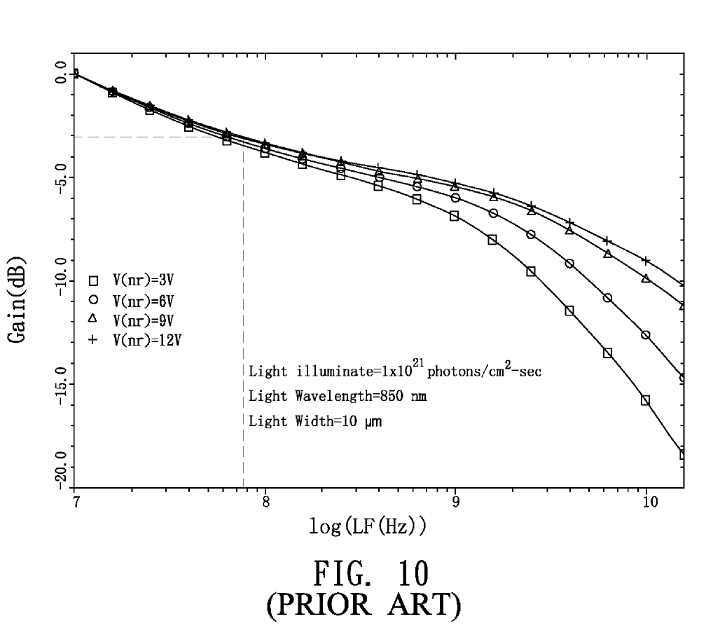

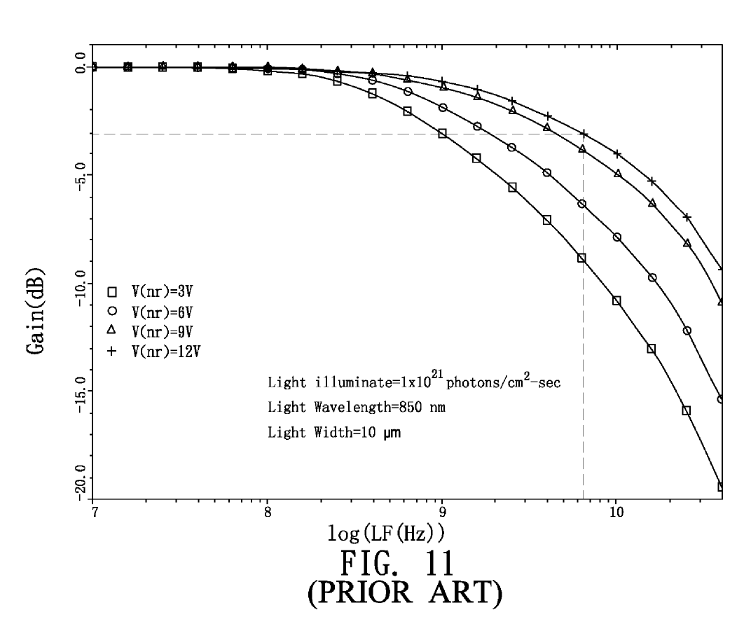

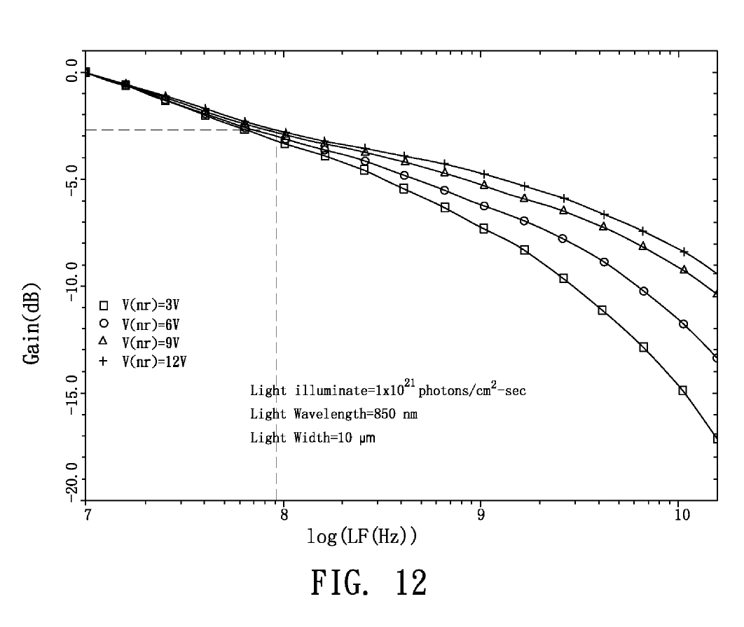

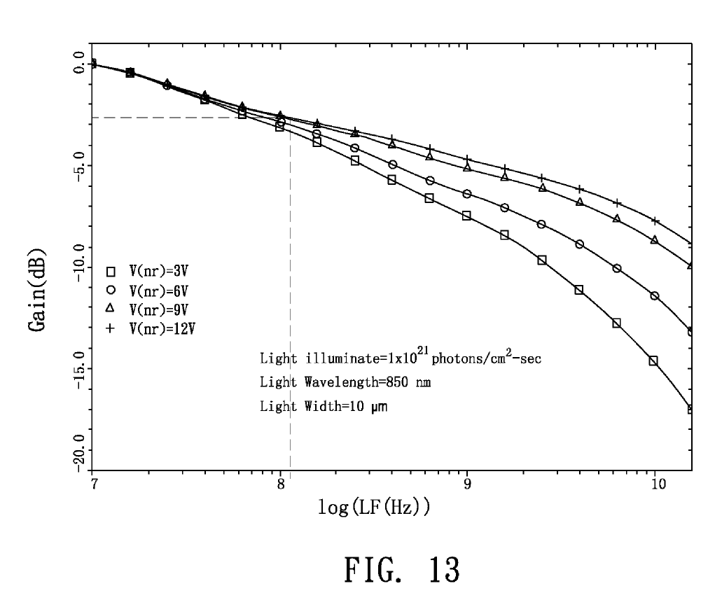

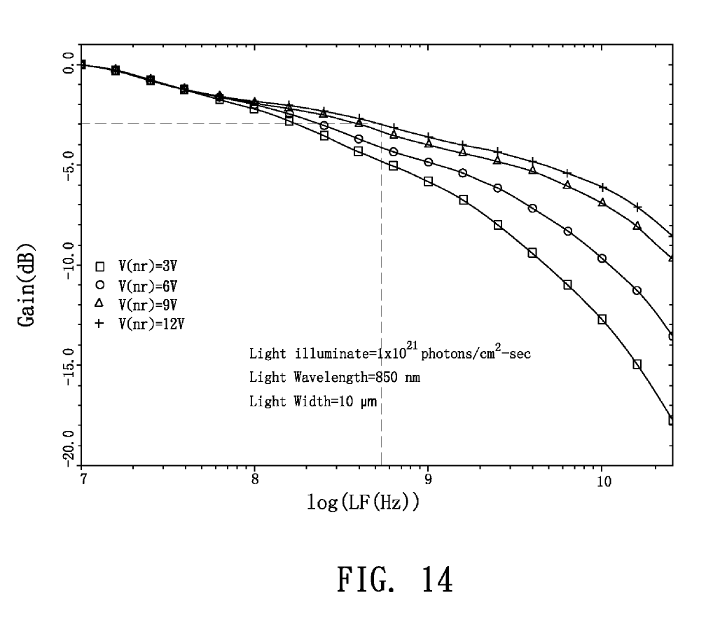

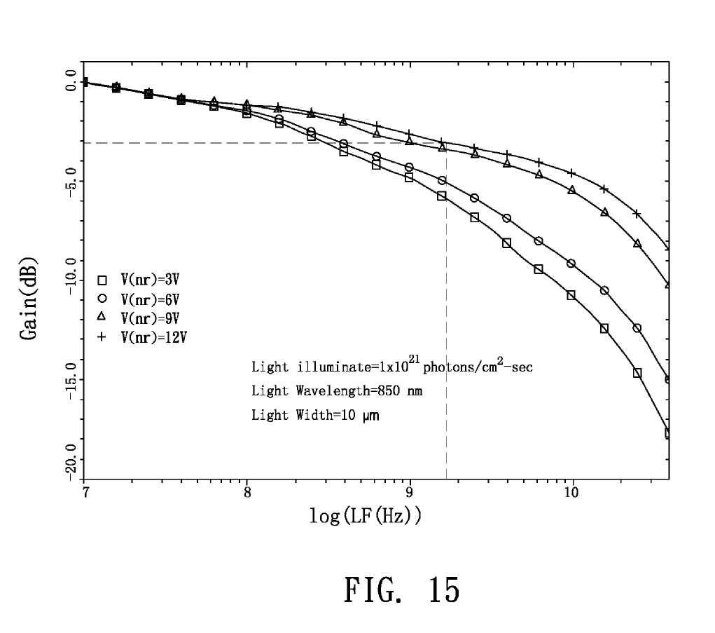

Referring to FIG. 10 through FIG. 15, simulated optical responses of the conventional structure (FIG. 10), the structure with silicon on the insulating layer (FIG. 11) and the inventive structure with different etching depths (FIG. 12 through FIG. 15) are respectively shown therein. Referring to FIG. 10, a negative 3 dB bandwidth is 75 MHz when a negative bias voltage 12V is provided. Referring to FIG. 15, the lateral etched structure has a negative 3 db bandwidth of 1.8 GHz, which corresponds to a promotion of approximately 24 times in speed. Apparently, the inventive structure is demonstrated as being benefited with an improved optical responsive speed due to elimination of a large portion of the slow carriers. As the applied negative bias voltage becomes larger, the electric field applied is larger which causes a depletion region of the photodetector to be also larger. At this time, the bandwidth becomes larger due to the electric field speeding up the carriers and the optical response also becomes more significant as the depletion region increases.

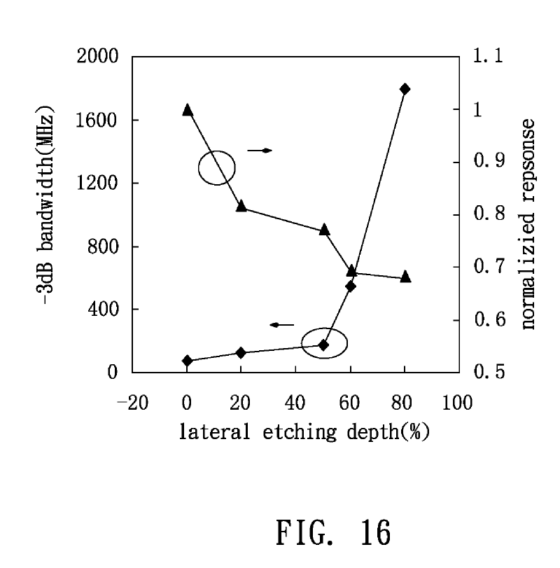

Referring to FIG. 16, an optical responsive speed and response plot of the inventive structures with respective depths of 2, 4, 6 and 8 μm resulted from the lateral etching process is shown therein. It can be appreciated that the optical responsive speed of the photodetector can be promoted after the substrate underlying the photodetector is subject to the lateral etching process, and the optical responsive speed of the photodetector increases as the etched depth increases.

According to the above, a greater level of the lateral etching process on the photodetector structure may cause a more enhanced optical response speed of the photodetector, but the etched depth should be limited to an extent where the substrate can barely endure. Specifically, the lateral etching is conducted downward and inward with respect to the photodetector structure.

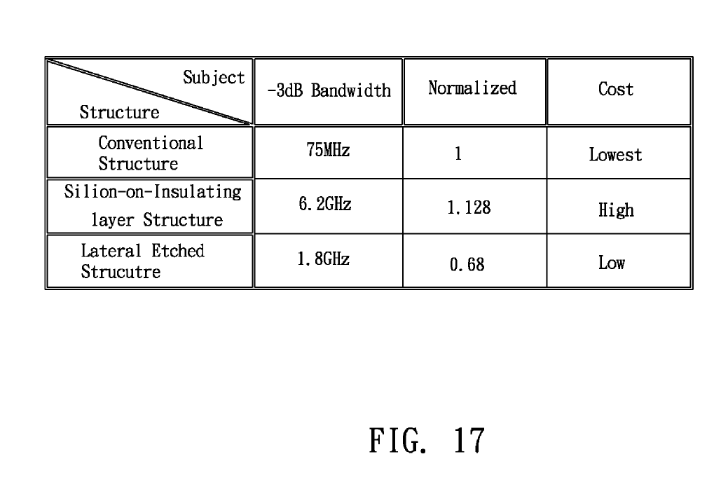

Referring finally to FIG. 17, the photodetector structure with the silicon-on-insulating layer feature has the greatest speed and also has the highest cost. The inventive photodetector having been subject to the lateral etching process is less than the photodetector structure with the silicon-on-insulating layer in speed but has a commensurate cost as compared thereto. And the optical response speed of the inventive photodetector is much enhanced, compared with the conventional photodetector. Accordingly, the laterally etched photodetector is a practicable novel structure.

It is readily apparent that the above-described embodiments have the advantage of wide commercial utility. It should be understood that the specific form of the invention hereinabove described is intended to be representative only, as certain modifications within the scope of these teachings will be apparent to those skilled in the art. Accordingly, reference should be made to the following claims in determining the full scope of the invention.

What is claimed is:

1. A method for fabricating a silicon photodetector, comprising the steps of:
forming a prototype of the silicon photodetector by using a traditional process for forming a complemented metal oxide semiconductor (CMOS) process; and
applying a process for forming a micro-electromechanical system manufacturing process onto the prototype to eliminate a substrate formed under a bottom of the prototype, wherein the micro-electromechanical system process is a lateral etching process.

2. A silicon photodetector formed by the method as claimed in claim 1, forming a prototype of the silicon photodetector by using a traditional process for forming a complemented metal oxide semiconductor (CMOS) process; and
applying a process for forming a micro-electromechanical system process onto the prototype to eliminate a substrate formed under a bottom of the prototype, wherein the micro-electromechanical system process is a lateral etching process.

3. The silicon photodetector as claimed in claim 2, wherein the substrate under the prototype of the silicon photodetector is only and right etched up to an extent where a notch formed by the lateral etching process can be endured by the substrate.
